(19) United States
(12) Patent Application Publication
(10) Pub. No.: US 2025/0243394 A1
(43) Pub. Date: Jul. 31, 2025

(54) COMPOSITIONS COMPRISING A DIELECTRIC FLUID AND A PHASE-CHANGE FLUID AND USES THEREOF

(71) Applicant: THE CHEMOURS COMPANY FC, LLC, Wilmington, DE (US)

(72) Inventors: MICHAEL R. FRASER, Quakertown, PA (US); Raymond Wu, Mount Laurel, NJ (US)

(73) Assignee: THE CHEMOURS COMPANY FC, LLC, Wilmington, DE (US)

(21) Appl. No.: 19/010,321

(22) Filed: Jan. 6, 2025

Related U.S. Application Data
(60) Provisional application No. 63/626,156, filed on Jan. 29, 2024.

(51) Int. Cl. C09K 5/04; H05K 7/20

(52) U.S. Cl. CPC C09K 5/04; H05K 7/203

(57) ABSTRACT

The present disclosure provides compositions including a dielectric fluid and a phase-change fluid. The present disclosure also provides for methods of use for the compositions. The compositions are particularly useful in cooling applications.

### CROSS REFERENCE TO RELATED APPLICATIONS

This application claims the benefit of priority of U.S. Application No. 63/626,156 filed Jan. 29, 2024, which is incorporated by reference herein in its entirety.

### FIELD OF DISCLOSURE

The present disclosure is in the field of compositions including a dielectric fluid and a phase-change fluid. These compositions are particularly useful in cooling applications.

### BACKGROUND

The use of two-phase immersion cooling has become an increasingly popular method for thermal management in emerging technologies, like data center servers, computers, and electric vehicle battery packs, due to the very reliably narrow range of operating temperatures, high efficiency, and simplicity compared to closed-loop single phase cooling methods. Such closed-loop single phase cooling methods require pumps, heat exchangers, fans, and thermostats, among other components, to maintain a given temperature range, and therefore require more complex setups compared to two-phase immersion cooling.

Two-phase immersion cooling relies on the boiling of an immersion coolant to remove heat from the device it is in direct contact with, and thus maintains the operating temperature at the boiling point of the fluid. Ideally, effective immersion cooling fluids in direct contact with electrically charged components require a low dielectric constant, high breakdown voltage, and excellent thermal stability and material compatibility for constant, long-term interaction with all components of the device it is cooling. Additionally, two-phase immersion fluids must be non-flammable and have a boiling point within the desired operating temperature of the device.

Perfluorocarbons (PFC's), such as perfluoro(N-methylmorpholine) (e.g., Fluorinert™ FC-3284) and perfluorohexane (e.g., Fluorinert™ FC-72), have commonly been used in two-phase immersion cooling applications. Such perfluorocarbons have boiling points between 50° C. and 60° C. and dielectric constants of less than 2. However, these PFC's have very high atmospheric lifetime and thus have global warming potentials (GWP) of over 9,000. Other classes of lower GWP fluorinated materials such as hydrofluorocarbons (HFC's), hydrofluoroethers (HFE's), and hydrofluoroolefins (HFO's) have been made commercially available, but generally have inferior dielectric properties.

Other classes of non-flammable, lower boiling dielectric fluids have been evaluated, such as blends of trans-1,2-dichloroethylene and other non-polar chlorinated solvents, but these fluids can negatively affect many plastics commonly used in electronics, especially after long term use.

Perfluoropolyether (PFPE) materials, such as Krytox™ and Galden™ branded products, have been used extensively in demanding applications due to excellent thermal stability, broad material compatibility, and low dielectric constants. These PFPE materials are marketed for their excellent chemical resistance and very low solubility with many common solvents, including trans-1,2-dichloroethylene. However, the higher boiling points of these fluids have limited them solely to single-phase cooling use.

Thus, there is a need for improved immersion fluids that provide effective heat transfer while being compatible with electronic components.

### BRIEF DESCRIPTION

The present disclosure provides a composition comprising a dielectric fluid and a phase-change fluid, wherein the dielectric fluid and the phase-change fluid are immiscible, and wherein the dielectric fluid has a boiling point greater than a boiling point of the phase-change fluid.

The present disclosure also provides an immersion cooling unit including an immersion cell defining an internal cavity. An electronic or electrical component is positioned in the internal cavity. A working fluid partially fills the internal cavity and includes a composition comprising a dielectric fluid and a phase-change fluid, wherein the dielectric fluid and the phase-change fluid are immiscible, and wherein the dielectric fluid has a boiling point greater than a boiling point of the phase-change fluid. The dielectric fluid at least partially immerses the energy storage device, IT equipment, computer server etc.

The present disclosure also provides a method for cooling electrically charged equipment, such as but not limited to energy storage devices (such as batteries), IT equipment, computer servers including those used in data centers and crypto currency mining applications. The method includes at least partially immersing an electrical component in a dielectric fluid of a working fluid; and transferring heat from the electrical component using the working fluid; wherein the working fluid includes a composition comprising the dielectric fluid and a phase-change fluid, wherein the dielectric fluid and the phase-change fluid are immiscible, and wherein the dielectric fluid has a boiling point greater than a boiling point of the phase-change fluid.

The present disclosure also provides a method for replacing a working fluid in an immersion cooling system. The method includes charging an immersion cooling system that was designed for use with a working fluid with a composition comprising a dielectric fluid and a phase-change fluid, wherein the dielectric fluid and the phase-change fluid are immiscible, and wherein the dielectric fluid has a boiling point greater than a boiling point of the phase-change fluid.

### BRIEF DESCRIPTION OF THE DRAWINGS

Embodiments are illustrated in the accompanying figures to improve understanding of concepts as presented herein.

FIG. 1A is a perspective view of an immersion unit in accordance with the present disclosure.

FIG. 1B is a perspective view of an immersion unit in accordance with the present disclosure.

FIG. 2A is a perspective view of an immersion unit in accordance with the present disclosure.

FIG. 2B is a perspective view of an immersion unit in accordance with the present disclosure.

FIG. 3 is a pool boiling curve in accordance with the present disclosure.

FIG. 4 depicts boiling point measurements of HFO-1336mzzZ and dielectric oil mixtures in accordance with the present disclosure.

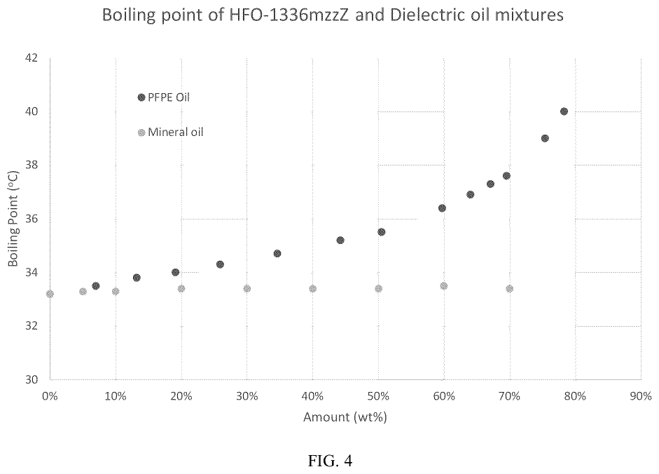

FIG. 5 depicts boiling point measurements of dichloromethane and dielectric oil mixtures in accordance with the present disclosure.

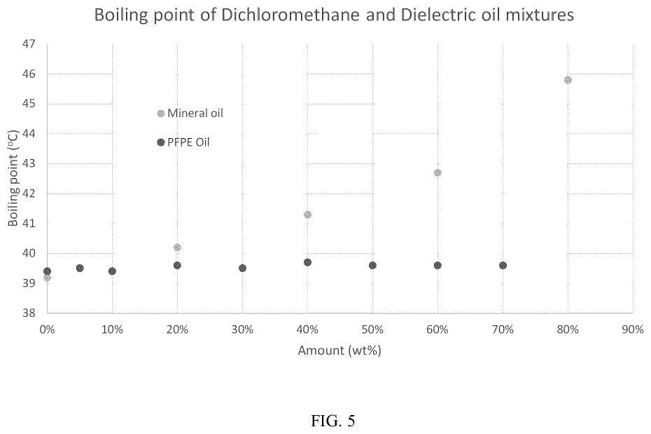

### DETAILED DESCRIPTION

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present disclosure, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

Many aspects and embodiments have been described above and are merely exemplary and not limiting. After reading this specification, skilled artisans appreciate that other aspects and embodiments are possible without departing from the scope of the invention.

Described herein are compositions comprising a dielectric fluid and a phase-change fluid, wherein the dielectric fluid and the phase-change fluid are immiscible, and wherein the dielectric fluid has a boiling point greater than a boiling point of the phase-change fluid.

As used herein, immiscible fluids possess a solubility between phases of less than 10%.

Generally, the dielectric fluid and the phase-change fluid possess different densities. The combination of immiscibility and different densities provides separation between the dielectric fluid and the phase-change fluid.

In some embodiments, the dielectric fluid is more dense than the phase-change fluid. In these embodiments, the phase-change fluid is disposed on top of the dielectric fluid in mixtures including the dielectric fluid and the phase-change fluid in contact.

In some embodiments, the dielectric fluid is less dense than the phase-change fluid. In these embodiments, the dielectric fluid is disposed on top of the phase-change fluid in mixtures including the dielectric fluid and the phase-change fluid in contact.

The immiscibility of the dielectric fluid and the phase-change fluid is a feature used to control the operating temperature of the dielectric fluid via boiling of the phase-change fluid. While soluble mixtures of dielectric oils with phase change fluids may have significant differences between the boiling point and dew point (i.e., glide), immiscible mixtures have a dew point and boiling point that are substantially the same temperature as the boiling point of the phase-change fluid. This is advantageous as emissive losses will not substantially increase the operating temperature due to changes in composition. Further, soluble mixtures with significant glide and lower dew points will require condensing systems to operate at lower temperatures to reject the heat to surroundings.

Beyond the constant operating temperature, another benefit of the immiscibility of the dielectric fluid and the phase-change fluid is the unchanged chemical characteristics of the dielectric fluid used for immersion, including dielectric constant, material compatibility, and thermal stability. While soluble mixtures of dielectric fluids with lower resistivity phase-change fluids may negatively affect the dielectric properties, immiscible mixtures with minimal solubility between phases preserves the dielectric properties of the dielectric fluid. In addition, the non-volatile nature of certain dielectric fluids, such as PFPE oils or mineral oils, may offer better thermal management in emergency situations or when left unattended, as the immersed equipment will remain insulated up to extreme temperatures even as the volatile fluid evaporates.

Additionally, use of the immiscibility of the dielectric fluid and the phase-change fluid expands the possible phase-change fluids that can be used, since the contacting of a heat generating (e.g., electrically-charged) device with aggressive solvents or lower resistivity polar fluids is avoided. Whereas PFC's have a very low heat of vaporization, this may permit the use of other fluids with much higher heat of vaporization, which improves performance and reduces fluid needed per kW generated.

| | | Volume | Heat of | |
|---|---|---|---|---|
| | Dielectric | Resistivity | vaporization | Density |
| Fluid | Constant | (Ω-cm) | (kJ/kg) | (g/mL |
| Perfluorohexane | 1.9 | 1.00E+15 | 88 | 1.68 |
| Perfluoro(N- | 1.9 | 1.00E+15 | 105 | 1.71 |
| methylmorpholine) | | | | |
| Nonafluorobutyl | 7.4 | 1.00E+08 | 112 | 1.52 |
| methyl ether | | | | |
| HFO-1336mzzZ | >10 | 1.00E+08 | 164 | 1.36 |
| HFE-347pcF | 6.6 | <1.0E06 | 154 | 1.48 |
| HFC-4310mee | 7.2 | 1.00E+09 | 127 | 1.58 |
| trans-1,2- | 2.0 | 1.00E+14 | 290 | 1.29 |
| dichloroethylene | | | | |
| Dichloromethane | >10 | <1.00E+06 | 332 | 1.33 |
| 60% Mineral | 2.0 | 5.00E+13 | 164 | — |
| oil/40% HFO- | | | | |
| 1336mzzZ | | | | |
| (insoluble) | | | | |
| 60% Mineral oil/ | 4 | 2.00E+10 | 332 | 0.96 |
| 40% | | | | |
| dichloromethane | | | | |
| (soluble) | | | | |
| 60% PFPE Oil/40% | 2.1 | 1.00E+13 | 332 | — |
| dichloromethane | | | | |
| (insoluble) | | | | |
| 60% PFPE oil/40% | 7.25 | 1.00E+10 | 164 | 1.58 |
| HFO-1336mzzZ | | | | |
| (soluble | | | | |

Immiscible combinations of dielectric fluids and phase-change fluids as shown in the table above may enable the use of phase-change fluids with higher heat of vaporization and inferior dielectric properties.

In some embodiments, the dielectric fluid comprises a component selected from the group consisting of perfluoropolyether oils, perfluorocarbons, perfluorohexane, perfluoroalkenes, perfluoroheptene, perfluoroketones, dodecafluoro-2-methyl pentan-3-one, mineral oils, alkanes having at least eight carbon atoms, silicone oils, polyol ester oils, polyalkylene glycol oils, and combinations thereof.

In some embodiments, the dielectric fluid has a dielectric constant less than about 8. In some embodiments, the dielectric fluid has a dielectric constant less than 7.3, or less than 5.5, or less than 5.0, or less than 4.0, or less than 3.5, or less than 2.7. In some embodiments, the dielectric fluid has a dielectric constant greater than 1.0 and less than 8.0 or greater than 2.0 and less than 7.3 or greater than 2.5 and less than 5.5 or greater than 3.5 and less than 5.0.

In some embodiments, the phase-change fluid comprises a component selected from the group consisting of trans-dichloroethylene, methylene chloride, acetone, cyclopentane, 2-methylpentane, hydrofluoroolefins having a boiling point in a range of from about 30° C. to about 75° C., HFO-1336mzzZ, hydrofluoroethers having a boiling point in a range of from about 30° C. to about 75° C., HFE-347pcF, and combinations thereof.

In some embodiments, the dielectric fluid is a fluorinated dielectric fluid and wherein the phase-change fluid is a non-fluorinated phase-change fluid.

In some embodiments, the dielectric fluid comprises a component selected from the group consisting of perfluoropolyether oils, perfluorocarbons, perfluorohexane, perfluoroalkenes, perfluoroheptene, perfluoroketones, dodecafluoro-2-methylpentan-3-one, and combinations thereof, and wherein the phase-change fluid comprises a component selected from the group consisting of trans-dichloroethylene, methylene chloride, acetone, cyclopentane, 2-methylpentane, and combinations thereof.

In some embodiments, the dielectric fluid comprises perfluorohexane and wherein the phase-change fluid comprises methylene chloride.

In some embodiments, the dielectric fluid comprises a perfluoropolyether oil and wherein the phase-change fluid comprises trans-dichloroethylene.

In some embodiments, the dielectric fluid is a hydrocarbon dielectric fluid and wherein the phase-change fluid is a fluorinated phase-change fluid.

In some embodiments, the dielectric fluid comprises a component selected from the group consisting of mineral oils, alkanes having at least eight carbon atoms, silicone oils, polyol ester oils, polyalkylene glycol oils, and combinations thereof.

In some embodiments, the phase-change fluid comprises a component selected from the group consisting of hydrofluoroolefins having a boiling point in a range of from about 30° C. to about 75° C., HFO-1336mzz-Z, hydrofluoroethers having a boiling point in a range of from about 30° C. to about 75° C., HFE-347pcF, and combinations thereof.

In some embodiments, the phase-change fluid comprises a hydrofluoroolefin having a boiling point in a range of from about 30° C. to about 75° C., preferably from about 30° C. to about 60° C., even more preferably from about 45° C. to about 55° C.

In some embodiments, the phase-change fluid comprises a hydrofluoroether having a boiling point in a range of from about 30° C. to about 75° C., preferably from about 30° C. to about 60° C., even more preferably from about 45° C. to about 55° C.

In some embodiments, the dielectric fluid comprises a component selected from the group consisting of mineral oils, alkanes having at least eight carbon atoms, silicone oils, polyol ester oils, polyalkylene glycol oils, and combinations thereof, and wherein the phase-change fluid comprises a component selected from the group consisting of hydrofluoroolefins having a boiling point in a range of from about 30° C. to about 75° C., HFO-1336mzz-Z, hydrofluoroethers having a boiling point in a range of from about 30° C. to about 75° C., HFE-347pcF, and combinations thereof.

In some embodiments, the dielectric fluid comprises a mineral oil and wherein the phase-change fluid comprises HFO-1336mzzZ.

In some embodiments, the dielectric fluid is a mixture of dielectric fluids. In some embodiments, dielectric fluid is a mixture of mineral oil and polyalkylene glycol (PAG) oil. In some embodiments, dielectric fluid is a mixture of mineral oil and polyol ester (POE) oil.

Generally, the working fluid may include any suitable amount of dielectric fluid that immerses and insulates a device. In some embodiments, the working fluid includes the dielectric fluid in an amount in a range of from about 5 wt % to about 95 wt %. In some embodiments, the working fluid includes the dielectric fluid in an amount in a range of from about 10 wt % to about 90 wt %. In some embodiments, the working fluid includes the dielectric fluid in an amount in a range of from about 20 wt % to about 80 wt %. In some embodiments, the working fluid includes the dielectric fluid in an amount in a range of from about 30 wt % to about 70 wt %. In some embodiments, the working fluid includes the dielectric fluid in an amount in a range of from about 40 wt % to about 60 wt %.

Generally, the working fluid may include any suitable amount of phase-change fluid that removes heat from the dielectric fluid. In some embodiments, the working fluid includes the phase-change fluid in an amount in a range of from about 5 wt % to about 95 wt %. In some embodiments, the working fluid includes the phase-change fluid in an amount in a range of from about 10 wt % to about 90 wt %. In some embodiments, the working fluid includes the phase-change fluid in an amount in a range of from about 20 wt % to about 80 wt %. In some embodiments, the working fluid includes the phase-change fluid in an amount in a range of from about 30 wt % to about 70 wt %. In some embodiments, the working fluid includes the phase-change fluid in an amount in a range of from about 40 wt % to about 60 wt %.

In some embodiments, the compositions of the present application further comprise stabilizers that reduce degradation over time and elevated temperatures.

In some embodiments, the compositions of the present application further comprise an additional component selected from the group consisting of one or more antioxidants and one or more acid scavengers, or any mixture thereof.

In some embodiments, the one or more acid antioxidants are selected from butylated hydroxy toluene (BHT), hydroquinone monomethyl ether (HQMME), amylene, 2-tert-butyl-6-methylphenol, 2-tert-butyl-5-methylphenol and 2-tert-butyl-4-ethylphenol. In some embodiments, the one or more scavengers are selected from 1,3-dioxolane, 1,2-epoxybutane and nitromethane.

Large scale computer server systems can perform significant workloads and generate a large amount of heat during their operation. A significant portion of the heat is generated from their operation. Due in part to the amount of heat generated, these systems are typically mounted in stacked configurations with large internal cooling fans and heat dissipating fins. As the size and density of these systems increases the thermal challenges are even greater, and eventually outpace the ability for forced air systems.

Two-phase immersion cooling is an emerging cooling technology for the high performance cooling market as applied to high performance high power density server systems, IT equipment used in Data centers, crypto currency mining facilities. It relies on the heat absorbed in the process of vaporizing an immersion liquid into a gas. The fluids used in this application must meet certain requirements to be viable in use. For example, the boiling temperature of the fluid should be in the range between 30-75° C. Generally, this range accommodates maintaining the server components at a sufficiently cool temperature while allowing generated heat to be dissipated sufficiently to an external heat sink. Alternatively, the operating temperature of the server, and the immersion cooling system could be raised or lowered, by using an enclosed system and raising or lowering the pressure within the system to raise or lower the boiling point of a given fluid.

Single phase immersion cooling has a long history in computer server cooling. There is no phase change in single phase immersion cooling. Instead, the liquid warms as it circulates through the computer server or heat generating device, and then is circulated with a pump to a heat exchanger for cooling prior to returning to the server or heat generating device, thus transferring heat away from those components. Fluids used for single phase immersion cooling have the same requirements as those for two-phase immersion cooling, except that the boiling temperatures are typically higher than 30-75° C., to reduce loss by evaporation.

Provided is an immersion cooler having an operating temperature range near ambient temperatures. Some embodiments of the present disclosure, for example, in comparison to concepts failing to include one or more of the features disclosed herein, provide an immersion cooler having fluids providing one or more of a controlled boiling point, no glide, unchanged chemical characteristics of an immersion oil, and greater selection in possible phase-change fluids.

Also provided is a method of immersion cooling wherein the device is a heat generating component, comprising at least partially immersing the heat generating component into a dielectric fluid of an immersion cooling fluid, and transferring heat from the heat generating component to the dielectric fluid. It is preferable in these embodiments to immerse the heat generating component in the dielectric fluid, but not the phase-change fluid, of the immersion cooling fluid.

Such devices include high capacity energy storage devices, electrical components, IT equipment, computer servers, mechanical components and optical components. Examples of devices of the present disclosure include, but are not limited to, microprocessors, wafers used to manufacture semiconductor devices, power control semiconductors, electrical distribution switch gear, power transformers, circuit boards, multi-chip modules, packaged and unpackaged semiconductor devices, laser, fuel cells, electrochemical cells and energy storage devices such as batteries. In some embodiments, the device is an electronic component selected from: high-capacity energy storage devices, computer servers, datacenter servers, GPUs, CPUs, solar photovoltaics, batteries, insulated-gate bipolar transistor (IGBT) devices, telecommunication infrastructure, military electronics, televisions, cell phones, monitors, drones, automotive batteries, powertrains for electric vehicles, power electronics, avionics devices, power devices, power transformers, displays, microprocessors, wafers used to manufacture semiconductor devices, power control semiconductors, electrical distribution switch gear, circuit boards, multi-chip modules, packaged and unpackaged semiconductor devices, lasers, fuel cells, electrochemical cells, and combinations thereof. In some embodiments the device can include a chiller, a heater, or a combination thereof.

In certain embodiments, the devices can include electronic devices, such as processors, including microprocessors. Microprocessors typically have maximum operating temperatures of about 85° C., so effective heat transfer is required in conditions of high processing power, i.e. high heat rejection rates. In other embodiments, the devices may include energy storage systems, such as batteries. When rapidly charged or discharged, batteries can reject a significant amount of heat that needs to be effectively removed to avoid overheating, internal damage, thermal runaway to adjacent batteries and potentially fire. As these electronic and electric devices become denser, and more powerful, the amount heat generated per unit of time and volume increases. Therefore, the mechanism of heat transfer plays an important role in processor performance. The heat transfer fluid typically has good heat transfer performance, good electrical compatibility (even if used in “indirect contact” applications such as those employing cold plates), as well as low toxicity, low or nonflammability and low environmental impact. Good electrical compatibility suggests that the heat-transfer fluid candidate exhibit high dielectric strength, high volume resistivity, low dissipation factor, low dielectric constant and poor solvency for polar materials. Additionally, the heat-transfer fluid should exhibit good material compatibility, that is, it should not affect typical materials of construction in an adverse manner.

It is highly desirable that the new fluids have equivalent or superior heat transfer properties, including electronic surface-to-fluid thermal resistance, critical heat flux and fluid-to-condenser thermal resistance, compared to existing fluids so that they can replace these fluids in existing systems without significant loss in thermal performance or mechanical modifications; and in new systems designed for existing fluids without significant mechanical design changes. The practice of replacing an existing fluid with a new fluid in an existing system is often called “retrofit”.

It is also desirable that these fluids have similar normal boiling points compared to existing fluids so that they can be used to replace these in existing systems without significant mechanical or operational changes; and in new systems without significant mechanical design changes.

It is also highly desirable that the new fluids provide at least minimum dielectric properties required by the application, or even superior dielectric properties compared to existing fluids so that they can replace these fluids in existing systems without significant electrical or mechanical modifications; and in new systems designed for existing fluids without significant electrical or mechanical design changes. The desirable dielectric properties include high volume resistivity, low dielectric constant, high dielectric strength and low loss tangent.

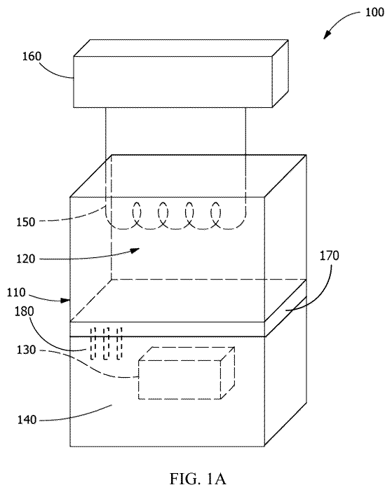

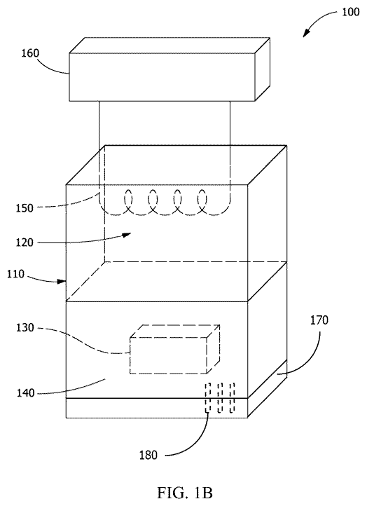

An embodiment of an immersion cooling unit 100 is shown in FIGS. 1A-1B. The immersion cooling system 100 includes an immersion cell 110 defining an internal cavity 120. A heat generating electrically charged component, (such as an energy storage device) 130, to be cooled, may be placed in the internal cavity 120. A dielectric fluid 140 of a working fluid partially fills the internal cavity 120. The dielectric fluid 140 at least partially immerses the energy storage device 130. In some embodiments, the dielectric fluid 140 substantially immerses the energy storage device 130. In one embodiment, the dielectric fluid 140 completely immerses the energy storage device 130. A phase-change fluid 170 of the working fluid is in fluidic contact with the dielectric fluid 140. The phase change fluid 170 may be on top of the dielectric fluid 140 as depicted in FIG. 1A, or the dielectric fluid 140 may be on top of the phase change fluid 170 as depicted in FIG. 1B. The phase-change fluid 170 is not in contact with the energy storage device 130. A thermally-conductive heat transfer device 180, such as thermally conductive fins or tubes made of aluminum or copper, may optionally be in contact with the phase-change fluid 170 of the working fluid and the dielectric fluid 140 of the working fluid to facilitate heat transfer. A condenser (e.g., a condensing coil, or more preferably, a recirculating, water-filled condensing coil) 150 is additionally present in the internal cavity 120. The condenser 150 may be spatially located above at least a portion of the dielectric working fluid 140 or the phase-change fluid 170.

During operation, heat generated by the electrical component 130, heats the dielectric fluid 140. This heat is transferred to the phase-change fluid 170, which causes a portion of the phase-change fluid 170 to vaporize. The phase-change fluid 170 vapors contact the condenser 150 cooled internally with chilled water above the phase-change fluid 170 and transfer thermal energy to the condenser 150 allowing the condensate phase-change fluid 170 to precipitate back into the liquid phase-change fluid 170 below. The thermal energy transferred to the chilled water in condenser 150 is transported external to the immersion cell 110 via a pump and released into the environment or to a chiller via an air-cooled radiator or other heat exchanger 160. The thermal energy released can also be recovered and used for heating applications or for energy generation such as Rankine cycles.

The phase-change fluids of the immersion cooler 100 are selected to undergo a phase transition from the liquid to the gaseous state over the operational temperature range of the immersion cooler 100. In some embodiments, the operational temperature is at least 25° C., at least 30° C., at least 40° C., at least 50° C., at least 60° C., less than 100° C., less than 90° C., less than 80° C., less than 70° C., less than 60° C., and combinations thereof.

In one embodiment the normal boiling point of the phase-change fluid may be within at least 10° C. of the fluid being replaced. In another embodiment the normal boiling point of the phase-change fluid may be within 8° C. In yet another embodiment, the normal boiling point of the phase-change fluid may be within 5° C.

The dielectric fluids 140 may also be selected to exhibit a dielectric constant, volume resistivity, dielectric strength and loss tangent (dissipation factor) suitable for direct contact with electrical components. In general, materials exhibiting a low dielectric constant, low loss tangent or dissipation factor, high volume resistivity and large dielectric strength provide increased electrical insulation of the energy storage device, or electrically charged components, 130, immersed therein as well as reduced signal loss. In some embodiments, the dielectric constant of the dielectric fluids 140 is less than about 8 over the operational frequency range (which can go as high as 100 GHz). Suitable dielectric fluids include compounds and mixtures having a dielectric constant over the operational frequency range (up to about 100 GHz) of less than 7.3, or less than 5.5, or less than 5.0, or less than 4.0, or less than 3.5, or less than 2.7. Other embodiments include compounds and mixtures having a dielectric constant greater than 1.0 and less than 8.0 or greater than 2.0 and less than 7.3 or greater than 2.5 and less than 5.5 or greater than 3.5 and less than 5.0.

Another characteristic of a good working fluid is that it possesses a high volume resistivity. Volume resistivity is an intrinsic property which measures how strongly a material resists electric current per unit length of a unit cross section, typically expressed in units of ohm-cm or ohm-m. A higher volume resistivity means the material is a better electrical insulator. The electrical resistance of material can be calculated by multiplying volume resistivity by the length and dividing by the cross-sectional area of the material.

So, a higher volume resistivity dielectric fluid is desirable as it leads to a higher electrical resistance and, consequently, a lower current leakage. Current leakage, for instance, can lead to self-discharge of energy storage devices such as batteries. It also means electrical components with different voltage can be placed closer (smaller “L”) for a given minimum resistance requirement, potentially leading to more compact assemblies. In one embodiment effective dielectric fluids have a volume resistivity, measured at 25° C. of at least 1×10¹⁰ ohm-cm. In another embodiment, an effective dielectric fluid has a volume resistivity of at least 1×10¹¹ ohm-cm. In another embodiment, an effective dielectric fluid has a volume resistivity of at least 1×10¹² ohm-cm. Water is known for having much lower volume resistivity. Thus, fluids with high volume resistivity are also desirable as, in case of the presence of water in the fluid, they would still maintain adequate levels of actual volume resistivity.

Another important dielectric fluid property is the dielectric strength which is defined as the maximum electric field or voltage, per unit of length, a material can resist without undergoing electrical breakdown and becoming electrically conductive. It is typically measured in units of kV/mm or kV/0.1″ gap. For a given distance or “gap”, the voltage at which a material becomes electrically conductive is called the breakdown voltage. A higher dielectric strength material is advantageous since it allows a higher voltage between two conductors or it allows two conductors to be placed closer, leading to potentially more compact assemblies. In one embodiment, the dielectric strength is greater than about 10 kV/0.1″ gap. In another embodiment, the dielectric strength is greater than about 20 kV/0.1″ gap. In yet another embodiment, the dielectric strength is greater than about 30 kV/0.1″ gap. In yet another embodiment, the dielectric strength is greater than about 35 kV/0.1″ gap.

All desirable dielectric properties aforementioned, high dielectric strength, low dielectric constant, low loss tangent and high volume resistivity must be present primarily in the dielectric fluid, but may also be present in the liquid or vapor phase of the phase-change fluid.

Other desirable characteristic of an immersion cooling fluid relates its ability of not significantly damaging, or not significantly reacting with, IT and computer parts such as cables, wires, seals, metals, among other parts, as well as constructions materials of the tank which are exposed to the dielectric fluid.

It is also desirable that these fluids have similar interactions with electronic components compared to the existing fluids so to minimize the replacement of parts.

Contaminant control measures, such as filter systems, may be used to remove solid or liquid residues that may be generated as a result of reactivity with materials of construction. Contamination control measures can also be used to maintain low enough acid and water levels.

Typical non-condensable gases, such nitrogen and oxygen, can also be present in the working fluid and can be detrimental to boiling and condensation heat transfer. Thus, systems with dielectric two-phase fluids may be equipped with a supplemental device that at least partially removes or controls the level of non-condensable levels in the dielectric fluid.

The ability of the working fluid to transport heat is related to the heat of vaporization of the phase change fluid. Typically, the greater the heat of vaporization of the phase change fluid, the greater amount of energy that the working fluid will absorb during vaporization and transport to the condenser 150 to be released during condensation.

It is also desirable that these fluids are non-flammable or present no flash point. Standards such as ASTM D56, D1310, and E681 can be used to assess flammability.

Since the objective of these fluids is to remove heat from energy storage devices, one important consideration is how good of a two-phase heat transfer the working fluid, and particularly the phase-change fluid, is. More specifically, how good of a heat transfer these fluids are under pool boiling conditions. Pool boiling heat transfer is typically divided into different modes or regimes:
1) Free convection: happens at small values of “wall superheat” or “excess temperature”—the difference between saturation temperature of the fluid and the wall or surface temperature
2) Nucleate boiling: occurs when there is high enough superheat for bubbles to form and separate from the surface, significantly improving heat transfer coefficient and heat flux. This mode is typically the preferred regime of boiling operation for heat removal. The nucleation boiling region is limited by the Critical Heat Flux (CHF) with units of kW/m². Heat transfer devices are usually designed to operate at heat fluxes lower than the CHF. The critical heat flux is particular to each fluid and depends on several thermophysical properties. It can be experimentally measured or estimated through semi-empirical models such as the one by Zuber (1958). Fluids with higher CHFs are desirable because they can remove more heat per unit of area, for a given wall superheat.
3) Transition boiling: a vapor film begins to form in the surface and there is an oscillation between nucleate and film boiling. The regime is unstable and not desirable to operate.
4) Film boiling: In this region the wall superheat is so high that a vapor blanket forms between the liquid and the surface—significantly reducing heat transfer coefficients. This region is also not desirable to operate.

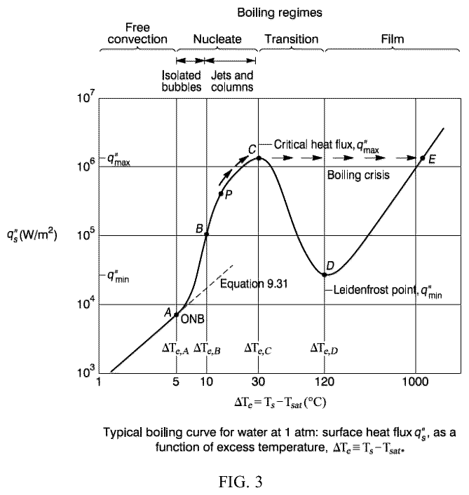

These regimes are illustrated in FIG. 3.

The present compositions may have improved CHFs compared to some existing fluids.

In one embodiment, the new fluids may be used to replace a dielectric fluid in an immersion cooling system. The new fluids may be used in this way by charging an immersion cooling system that was designed for use with a working fluid with a composition comprising a dielectric fluid and a phase-change fluid. In these embodiments, the dielectric fluid and the phase-change fluid are immiscible, and the dielectric fluid has a boiling point greater than a boiling point of the phase-change fluid.

In one embodiment, it is highly desirable that the new fluids provide an equivalent or higher critical heat flux than the existing fluids they are replacing. In another embodiment, the new fluids should provide a critical heat flux of no less than 90% of the critical heat flux of the existing fluids they are replacing. In yet another embodiment, the new fluid should provide a critical heat flux of no less than 80% of the critical heat flux of the existing fluids they are replacing so that there are no significant changes to the maximum heat flux dissipation in an existing immersion cooling system or major design changes to immersion cooling systems designed for existing fluids.

A higher boiling heat transfer coefficient is desirable as it leads to a lower overall thermal resistance, or a lower temperature of the electrical component being cooled. The boiling heat transfer coefficient and the electrical component-to-fluid thermal resistance can be improved with the use of surface enhancements which increase the number of nucleation sites.

The electrical component-to-fluid thermal resistance can be determined by the inverse of the product between boiling heat transfer coefficient and the heat transfer area of the electronic/electrical component.

In one embodiment, the electrical component-to-fluid thermal resistance of the new fluids must be lower or equivalent compared to the existing fluid. In another embodiment, the electrical component-to-fluid thermal resistance of the new fluids must be no more than 10% higher than that of the existing fluid. In yet another embodiment, the electrical component-to-fluid thermal resistance of the new fluids must be no more than 20% higher than that of the existing fluid, so there is no significant increase in temperature of an existing electronic device or no significant mechanical changes have to be implemented in a system design for an existing fluid.

Another important aspect of fluids used in two-phase immersion cooling systems is its condensation heat transfer coefficient. Higher condensation heat transfer are desirable as they lead to reduced vapor-to-condenser surface thermal resistance or lower temperature difference between the condensing vapor and the coolant that removes the heat. Condensation heat transfer can also be improved with surface enhancements.

The vapor-to-condenser surface thermal resistance can be determined by the inverse of the product between condensation heat transfer coefficient and the heat transfer area of the condenser.

In one embodiment, the vapor-to-condenser thermal resistance of the new fluids must be lower or equivalent compared to an existing fluid. In another embodiment, the vapor-to-condenser thermal resistance of the new fluids must be no more than 10% higher compared to an existing fluid. In yet another embodiment, the vapor-to-condenser thermal resistance of the new fluids must be no more than 20% higher compared to an existing fluid, so there is no significant drop in condenser performance or no significant mechanical changes, for instance an increase in heat transfer area, have to be implemented in the condenser designed for an existing fluid.

Combined higher boiling and condensation heat transfer coefficients are highly desirable as they reduce the overall thermal resistance between the coolant and the electronic or electrical equipment and reduce the temperature difference between the two. Better heat transfer coefficients yield better heat removal which, for instance, can allow batteries immersed in a dielectric liquid to be charged at a faster rate without leading to potential thermal runaway.

Heat transfer coefficients can be experimentally measured or calculated using experimentally determined heat transfer correlations combined with experimentally determined thermophysical properties.

The power usage or efficiency of data centers can be quantified in terms of PUE—Power Utilization Effectiveness. The lower the PUE or the closer to 1.0, the lower the energy utilized to remove a given amount of heat from data centers. It is highly desirable that immersion tanks with dielectric fluids lead to operate at PUE values close to 1.0. The PUE of an immersion cooling tank can be obtained by measuring the overall energy dissipated by the immersed electronic equipment and the energy consumed by the tank. Due to equivalent dielectric, thermodynamic and heat transfer properties, the fluids proposed can also be used to replace existing fluids in existing equipment in a practice often called “retrofit”. The retrofit could be partial when only a percentage of the existing fluid is replaced or full, when the entire fluid is replaced with a new fluid.

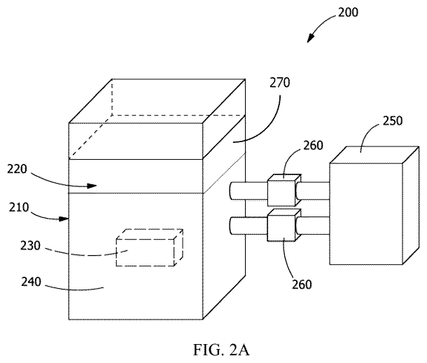

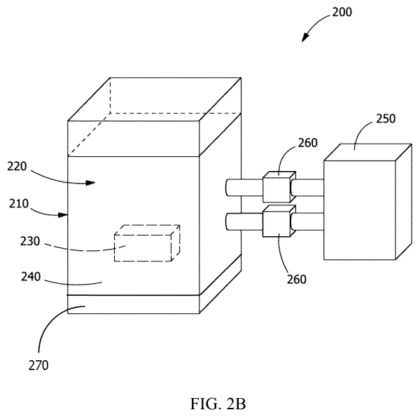

An embodiment of an immersion cooling unit 200 is shown in FIGS. 2A-2B. The immersion cooling system 200 includes an immersion cell 210 defining an internal cavity 220. A heat generating electrically charged component, (such as an energy storage device) 230, to be cooled, may be placed in the internal cavity 220. A dielectric fluid 240 of a working fluid partially fills the internal cavity 220. The dielectric fluid 240 at least partially immerses the energy storage device 230. In some embodiments, the dielectric fluid 240 substantially immerses the energy storage device 230. In one embodiment, the dielectric fluid 240 completely immerses the energy storage device 230. A phase-change fluid 270 of the working fluid is in fluidic contact with the dielectric fluid 240. The phase change fluid 270 may be on top of the dielectric fluid 240 as depicted in FIG. 2A, or the dielectric fluid 240 may be on top of the phase change fluid 270 as depicted in FIG. 2B. The phase-change fluid 270 is not in contact with the energy storage device 230.

A cooling unit 250 is positioned externally to the immersion cell 210. The cooling unit 250 is fluidly connected to the immersion cell 210. The cooling unit 250 is configured to fluidly receive at least a portion of the dielectric fluid 240 from the immersion cell 210. The cooling unit 250 is further configured to extract heat from the dielectric fluid 240, thereby reducing the temperature of the dielectric fluid 240. In one embodiment, the cooling unit 250 includes a heat exchanger. In one embodiment, the heat transferred to the cooling unit 250 is released into the environment or to a chiller via an air-cooled radiator or other heat exchanger. The thermal energy released can also be recovered and used for heating applications or for energy generation such as Rankine cycles. The cooling unit 250 is further configured to return the cooled dielectric fluid 240 to the immersion cooling cell 210. In some embodiments, a motive force may be provided to the dielectric fluid 240. In one embodiment, the motive force may be provided by one or more circulation pumps 260. In one embodiment, the motive force may be provided by convective flow.

The working fluids of the immersion cooler 200 are selected to be in the liquid state over the operational temperature range of the immersion cooler 200. In some embodiments, the operational temperature is at least 25° C., at least 30° C., at least 40° C., at least 50° C., at least 60° C., less than 100° C., less than 90° C., less than 80° C., less than 70° C., and combinations thereof.

Due to equivalent or better dielectric, thermodynamic and heat transfer properties, the fluids proposed can also be used to replace existing fluids in existing equipment in a practice often called “retrofit”.

While the invention has been described with reference to one or more embodiments, it will be understood by those skilled in the art that various changes may be made, and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

### EXAMPLES

The concepts described herein will be further described in the following examples, which do not limit the scope of the invention described in the claims. Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification is to be regarded in an illustrative, rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

### Example 1. Vapor and Liquid Phase Temperature Measurements of Immiscible HFO-1336mzzZ and Mineral Oil Mixtures Over a Range of Compositions

100 grams of HFO-1336mzzZ was decanted into a 1000 mL beaker equipped with a condensing coil, boiling chips, and thermocouple thermometer to measure liquid and vapor phase temperatures. The beaker was heated to the boiling point on a hot plate and the liquid phase boiling point and vapor phase dew point were recorded. Known amounts of mineral oil were then added to the beaker and given 5 minutes to equilibrate. A distinct, separate top liquid layer substantially of mineral oil was immediately observed, indicating minimal solubility between HFO-1336mzzZ and mineral oil. The temperature of this top layer was also recorded over the range of compositions.

| wt % | | | | Vapor |
|---|---|---|---|---|
| Mineral | | Top liquid | Bottom liquid | phase |
| Oil | Soluble? | phase (° C.) | phase (° C.) | (° C.) |
| 0% | N/A | N/A | 33.2 | 33 |
| 5% | No | 33.3 | 33.3 | 33 |
| 10% | No | 33.3 | 33.3 | 33.1 |
| 20% | No | 33.4 | 33.4 | 33.1 |
| 30% | No | 33.3 | 33.4 | 33.1 |
| 40% | No | 33.4 | 33.4 | 33.1 |
| 50% | No | 33.3 | 33.4 | 33 |
| 60% | No | 33.4 | 33.5 | 33.1 |
| 70% | No | 33.3 | 33.4 | 33.2 |

As shown in the table above, mixtures of HFO-1336mzzZ and mineral oil showed constant boiling of about 33° C. over the range of compositions. This is advantageous as emissive losses of HFO-1336mzzZ will not significantly change the operating temperature. Additionally, these mixtures exhibited minimal temperature difference in vapor phase and liquid phase, (i.e. minimal glide) which simplifies the condensing system design.

### Comparative Example 1. Vapor and Liquid Phase Temperature Measurements of Soluble HFO-1336mzzZ and PFPE Oil Mixtures

100 grams of HFO-1336mzzZ was decanted into a 1000 mL beaker equipped with a condensing coil, boiling chips, and thermocouple thermometer to measure liquid and vapor phase temperatures. The beaker was heated to the boiling point on a hot plate and the liquid phase boiling point and vapor phase dew point were recorded. Known amounts of PFPE oil were then added to the beaker and given 5 minutes to equilibrate. This was repeated over the range of compositions below, and the vapor and liquid temperature were recorded.

| wt % | | Boiling | Dew | |
|---|---|---|---|---|
| PFPE | | Point | Point | Glide |
| Oil | Soluble? | (° C.) | (° C.) | (ΔT) |
| 0.0% | Yes | 33.2 | 33.1 | 0.1 |
| 7.0% | Yes | 33.5 | 33.2 | 0.3 |
| 13.2% | Yes | 33.8 | 33.2 | 0.6 |
| 19.1% | Yes | 34 | 33.2 | 0.8 |
| 25.9% | Yes | 34.3 | 33.2 | 1.1 |
| 34.6% | Yes | 34.7 | 33.2 | 1.5 |
| 44.2% | Yes | 35.2 | 33.3 | 1.9 |
| 50.5% | Yes | 35.5 | 33.2 | 2.3 |
| 59.7% | Yes | 36.4 | 33.3 | 3.1 |
| 64.0% | Yes | 36.9 | 33.4 | 3.5 |
| 67.1% | Yes | 37.3 | 33.3 | 4.0 |
| 69.5% | Yes | 37.6 | 33.4 | 4.2 |
| 75.4% | Yes | 39 | 33.4 | 5.6 |
| 78.3% | Yes | 40 | 33.5 | 6.5 |

As shown in the table above, the boiling temperature of HFO-1336mzzZ and PFPE oil is composition-dependent, and thus emissive losses may change the operating temperature over time. Additionally, miscible mixtures of HFO-1336mzzZ and PFPE oil exhibited increasingly significant glide as PFPE content increased. Thus, soluble mixtures at a given operating temperature will require condenser temperatures significantly lower than the boiling point.

### Example 2. Vapor and Liquid Phase Temperature Measurements of Immiscible Dichloromethane and Perfluoropolyether (PFPE) Oil Mixtures Over a Range of Compositions

100 grams of dichloromethane was decanted into a 1000 mL beaker equipped with a condensing coil, boiling chips, and thermocouple thermometer to measure liquid and vapor phase temperatures. The beaker was heated to the boiling point on a hot plate and the liquid phase boiling point and vapor phase dew point were recorded. Known amounts of PFPE oil were then added to the beaker and given 5 minutes to equilibrate. A distinct, separate bottom liquid layer substantially of PFPE oil was immediately observed, indicating minimal solubility between dichloromethane and PFPE oil. The temperature of this top layer was also recorded over the range of compositions.

| wt % | | | | Vapor |
|---|---|---|---|---|
| PFPE | | Top liquid | Bottom liquid | phase |
| Oil | Soluble? | phase (° C.) | phase (° C.) | (° C.) |
| 0% | N/A | 39.4 | N/A | 39.3 |
| 5% | No | 39.5 | 39.8 | 39.4 |
| 10% | No | 39.4 | 39.7 | 39.2 |
| 20% | No | 39.6 | 39.8 | 39.3 |
| 30% | No | 39.5 | 39.7 | 39.3 |
| 40% | No | 39.7 | 39.7 | 39.4 |
| 50% | No | 39.6 | 39.8 | 39.4 |
| 60% | No | 39.6 | 39.7 | 39.5 |
| 70% | No | 39.6 | 39.8 | 39.3 |

As shown in the table above, mixtures of dichloromethane and PFPE oil showed constant boiling of about 33° C. over the range of compositions. This is advantageous as emissive losses of dichloromethane will not significantly change the operating temperature. Additionally, these mixtures exhibited minimal temperature difference in vapor phase and liquid phase, (i.e. minimal glide) which simplifies the condensing system design.

### Comparative Example 2. Vapor and Liquid Phase Temperature Measurements of Soluble Dichloromethane and Mineral Oil Mixtures

100 grams of dichloromethane was decanted into a 1000 mL beaker equipped with a condensing coil, boiling chips, and thermocouple thermometer to measure liquid and vapor phase temperatures. The beaker was heated to the boiling point on a hot plate and the liquid phase boiling point and vapor phase dew point were recorded. Known amounts of mineral oil were then added to the beaker and given 5 minutes to equilibrate. This was repeated over the range of compositions below, and the vapor and liquid temperature were recorded.

| wt % | | Boiling | Dew | |
|---|---|---|---|---|
| Mineral | | Point | Point | Glide |
| Oil | Soluble? | (° C.) | (° C.) | (ΔT) |
| 0.0% | Yes | 39.2 | 39.2 | 0.0 |
| 20.0% | Yes | 40.2 | 39.3 | 0.9 |
| 40.0% | Yes | 41.3 | 39.3 | 2.0 |
| 60.0% | Yes | 42.7 | 39.4 | 3.3 |
| 80.0% | Yes | 45.8 | 39.3 | 6.5 |

As shown in the table above, the boiling temperature of dichloromethane and mineral oil mixtures is composition-dependent, and thus emissive losses may change the operating temperature over time. Additionally, miscible mixtures of dichloromethane and mineral oil exhibited increasingly significant glide as mineral oil content increased. Thus, soluble mixtures at a given operating temperature will require condenser temperatures significantly lower than the boiling point.

### Example 3. Dielectric Properties of Immiscible Mixtures of HFO-1336mzzZ and Mineral Oil

A mixture of 40% HFO-1336mzzZ and 60% mineral oil was prepared by weight and decanted into the 1000 mL beaker equipped with a condensing coil and boiling chips. The mixture was heated to the atmospheric boiling point of about 33° C. and allowed to reflux for two hours. The top phase mineral oil was secured and analyzed for dielectric properties and compared to the dielectric values of unused mineral oil. As a comparison, a soluble mixture of 60% PFPE oil and 40% HFO-1336mzzZ was prepared by weight and analyzed for dielectric properties.

| | | Volume |
|---|---|---|
| | Dielectric | Resistivity |
| Test | Constant | (Ω-cm) |
| Mineral oil pre-test | 1.9 | 1.00E+15 |
| Mineral oil post- test | 1.98 | 1.00E+14 |
| Unused PFPE oil | 2.02 | 1.00E+14 |
| Unused HFO-1336mzzZ | >10 | 1.00E+8 |
| 60% PFPE oil/40% | 7.25 | 1.00E+10 |
| HFO-1336mzzZ | | |

As shown in the table above, the use of immiscible HFO-1336mzzZ did not significantly change the dielectric properties of the mineral oil top phase due to the minimal solubility. In comparison, in a miscible combination, addition of HFO-1336mzzZ to PFPE oil can negatively impact dielectric properties as the resistivity decreases and the dielectric constant increases. Thus, this immiscible method for immersion cooling can enable the use of a wider range of phase-change coolants even if their dielectric properties are not sufficient.

### Example 4. Dielectric Properties of Immiscible Mixtures of Dichloromethane and PFPE Oil

A mixture of 40% dichloromethane and 60% PFPE oil was prepared by weight and decanted into the 1000 mL beaker equipped with a condensing coil and boiling chips. The mixture was heated to the atmospheric boiling point of about 40° C. and allowed to reflux for two hours. The bottom phase PFPE oil was secured and analyzed for dielectric properties and compared to the dielectric values of unused mineral oil. As a comparison, a soluble mixture of 60% mineral oil and 40% dichloromethane was prepared by weight and analyzed for dielectric properties.

| | | Volume |
|---|---|---|
| | Dielectric | Resistivity |
| Test | Constant | (Ω-cm) |
| PFPE oil pre-test | 2.02 | 1.00E+14 |
| PFPE oil post-test | 2.1 | 1.00E+13 |
| Unused Mineral oil | 1.9 | 1.00E+15 |
| Unused | >10 | 1.00E+6 |
| dichloromethane | | |
| 60% mineral oil/40% | 3.5 | 1.00E+10 |
| dichloromethane | | |

As shown in the table above, the use of immiscible dichloromethane as a phase-change fluid did not significantly change the dielectric properties of the PFPE oil bottom phase due to the minimal solubility. In comparison, in a miscible combination, addition of dichloromethane to mineral oil can negatively impact dielectric properties as the resistivity decreases and the dielectric constant increases. Thus, this immiscible method for immersion cooling can enable the use of a wider range of phase-change coolants even if their dielectric properties are not sufficient.

### Example 5. Temperature Control of a Hydrocarbon Dielectric Oil by Substituting Fluorochemical Phase-Change Fluids

Mixtures of 60% ElectroCool™ EC-140 (hydrogenated dimer of 1-decene) with 40% of varying fluorinated heat transfer fluids were prepared by weight and heated to the boiling point as described in Example 1. Fluorinated heat transfer fluids include HFO-1336mzzZ, HFC-4310mee (Vertrel™ XF), perfluoroheptene (PFH), and HFE-347pcF. The temperature of the vapor phase and each liquid phase was monitored and recorded.

| | HFO- | | | |
|---|---|---|---|---|
| Property | 1336mzzZ | HFC-4310mee | HFE-347pcF | PFH |
| Fluorochemical nBP | 33 | 55 | 56 | 72 |
| (° C.) | | | | |
| Vapor Phase (° C.) | 32.8 | 54.4 | 55 | 71.8 |
| Top dielectric liquid | 33.6 | 54.6 | 55.6 | 72.4 |
| temperature (° C.) | | | | |
| Bottom phase-change | 33.8 | 54.5 | 56.1 | 72.5 |
| temperature (° C.) | | | | |

As shown above, the operating temperature of the immiscible immersion cooling technique using a hydrocarbon dielectric oil can be adjusted by substituting fluorochemical phase-change fluid with another fluorochemical or fluorochemical admixture.

### Example 6. Temperature Control of a Perfluoropolyether (PFPE) Oil by Substituting Immiscible Phase-Change Fluids

Mixtures of 60% PFPE oil with 40% of varying phase-change fluids were prepared by weight and heated to the boiling point as described in Example 1. Phase-change fluids include dichloromethane, trans-1,2-dichloroethylene (t-DCE), cyclopentane, and trichloroethylene (TCE).

| Property | DCM | t-DCE | Cyclopentane | TCE |
|---|---|---|---|---|
| Phase-change fluid nBP (° C.) | 40 | 49 | 49 | 87 |
| Vapor Phase (° C.) | 39.2 | 48.8 | 48.8 | 86.6 |
| Top phase-change liquid | 39.6 | 49.3 | 49.4 | 87.4 |
| temperature (° C.) | | | | |
| Bottom dielectric fluid | 39.9 | 49.5 | 49.8 | 87.8 |
| temperature (° C.) | | | | |

As shown above, the operating temperature of the immiscible immersion cooling technique using a perfluoropolyether dielectric fluid can be adjusted by substituting the phase-change fluid with another insoluble non-fluorochemical phase-change fluid or admixture.

### ADDITIONAL EMBODIMENTS

Any one or more of the composition, the immersion cooling unit, the method for cooling, and the method for replacing a working fluid disclosed herein may include one or more of the following aspects:
the dielectric fluid comprises a component selected from the group consisting of perfluoropolyether oils, perfluorocarbons, perfluorohexane, perfluoroalkenes, perfluoroheptene, perfluoroketones, dodecafluoro-2-methylpentan-3-one, mineral oils, alkanes having at least eight carbon atoms, silicone oils, polyol ester oils, polyalkylene glycol oils, and combinations thereof.
the dielectric fluid comprises a fluorinated dielectric fluid selected from the group consisting of perfluoropolyether oils, perfluorocarbons, perfluorohexane, perfluoroalkenes, perfluoroheptene, perfluoroketones, dodecafluoro-2-methylpentan-3-one, and combinations thereof.
the dielectric fluid comprises a hydrocarbon dielectric fluid selected from the group consisting of mineral oils, alkanes having at least eight carbon atoms, silicone oils, polyol ester oils, polyalkylene glycol oils, and combinations thereof.
the dielectric fluid has a dielectric constant less than 8.
the dielectric fluid has a dielectric constant greater than 1.0.
the dielectric fluid has a dielectric constant greater than 1.0 and less than 8.0.
the dielectric fluid has a dielectric constant greater than 2.0 and less than 7.3.
the dielectric fluid has a dielectric constant greater than 2.5 and less than 5.5.
the dielectric fluid has a dielectric constant greater than 3.5 and less than 5.0.
the phase-change fluid comprises a component selected from the group consisting of trans-dichloroethylene, methylene chloride, acetone, cyclopentane, 2-methylpentane, hydrofluoroolefins having a boiling point in a range of from about 30° C. to about 75° C., HFO-1336mzz-Z, hydrofluoroethers having a boiling point in a range of from about 30° C. to about 75° C., HFE-347pcF, and combinations thereof.
the phase-change fluid comprises a fluorinated phase-change fluid selected from the group consisting of hydrofluoroolefins having a boiling point in a range of from about 30° C. to about 75° C., HFO-1336mzz-Z, hydrofluoroethers having a boiling point in a range of from about 30° C. to about 75° C., HFE-347pcF, and combinations thereof.
the phase-change fluid comprises a non-fluorinated phase-change fluid selected from the group consisting of trans-dichloroethylene, methylene chloride, acetone, cyclopentane, 2-methylpentane, and combinations thereof.
the dielectric fluid is a fluorinated dielectric fluid and wherein the phase-change fluid is a non-fluorinated phase-change fluid.
the dielectric fluid comprises a component selected from the group consisting of perfluoropolyether oils, perfluorocarbons, perfluorohexane, perfluoroalkenes, perfluoroheptene, perfluoroketones, dodecafluoro-2-methylpentan-3-one, and combinations thereof, and wherein the phase-change fluid comprises a component selected from the group consisting of trans-dichloroethylene, methylene chloride, acetone, cyclopentane, 2-methylpentane, and combinations thereof.
the dielectric fluid comprises perfluorohexane and wherein the phase-change fluid comprises methylene chloride.
the dielectric fluid comprises a perfluoropolyether oil and wherein the phase-change fluid comprises trans-dichloroethylene.
the dielectric fluid is a hydrocarbon dielectric fluid and wherein the phase-change fluid is a fluorinated phase-change fluid.
the dielectric fluid comprises a component selected from the group consisting of mineral oils, alkanes having at least eight carbon atoms, silicone oils, polyol ester oils, polyalkylene glycol oils, and combinations thereof, and wherein the phase-change fluid comprises a component selected from the group consisting of hydrofluoroolefins having a boiling point in a range of from about 30° C. to about 75° C., HFO-1336mzzZ, hydrofluoroethers having a boiling point in a range of from about 30° C. to about 75° C., HFE-347pcF, and combinations thereof.
the dielectric fluid comprises a mineral oil and wherein the phase-change fluid comprises HFO-1336mzzZ.
the heat transfer device is a condenser positioned in the internal cavity above the electronic component.
the heat transfer device is a remote heat sink, wherein the remote heat sink is configured to receive the working fluid from a pump.
the dielectric working fluid does not immerse the condenser.
an operating temperature range is between 40° C. and 80° C.
the volume resistivity of the dielectric working fluid is at least 1×10¹⁰ Ω-cm.
the electronic component comprises at least one component selected from the group consisting of high-capacity energy storage devices, computer servers, datacenter servers, GPUs, CPUs, solar photovoltaics, batteries, insulated-gate bipolar transistor (IGBT) devices, telecommunication infrastructure, military electronics, televisions, cell phones, monitors, drones, automotive batteries, powertrains for electric vehicles, power electronics, avionics devices, power devices, power transformers, displays, microprocessors, wafers used to manufacture semiconductor devices, power control semiconductors, electrical distribution switch gear, circuit boards, multi-chip modules, packaged and unpackaged semiconductor devices, lasers, fuel cells, electrochemical cells, and combinations thereof.
transferring of heat occurs through pumping of said working fluid from the electrical component to be cooled to a remote heat sink.
transferring of heat occurs through vaporization of said phase-change fluid, and condensing said phase-change fluid vapor through contact with a heat sink.
the electrical component to fluid thermal resistance of the replacement fluid is lower than or equivalent to said working fluid.
the electrical component to fluid thermal resistance of the replacement fluid is no higher than 20% greater than that of said working fluid.
the electrical component to fluid thermal resistance of the replacement fluid is no higher than 10% greater than that of said working fluid.

1. A composition comprising a dielectric fluid and a phase-change fluid, wherein the dielectric fluid and the phase-change fluid are immiscible, and wherein the dielectric fluid has a boiling point greater than a boiling point of the phase-change fluid.

2. The composition of claim 1, wherein the dielectric fluid comprises a component selected from the group consisting of perfluoropolyether oils, perfluorocarbons, perfluorohexane, perfluoroalkenes, perfluoroheptene, perfluoroketones, dodecafluoro-2-methylpentan-3-one, mineral oils, alkanes having at least eight carbon atoms, silicone oils, polyol ester oils, polyalkylene glycol oils, and combinations thereof.

3. The composition of claim 1, wherein the dielectric fluid comprises a fluorinated dielectric fluid selected from the group consisting of perfluoropolyether oils, perfluorocarbons, perfluorohexane, perfluoroalkenes, perfluoroheptene, perfluoroketones, dodecafluoro-2-methylpentan-3-one, and combinations thereof.

4. The composition of claim 1, wherein the dielectric fluid comprises a hydrocarbon dielectric fluid selected from the group consisting of mineral oils, alkanes having at least eight carbon atoms, silicone oils, polyol ester oils, polyalkylene glycol oils, and combinations thereof.

5. The composition of claim 1, wherein the phase-change fluid comprises a component selected from the group consisting of trans-dichloroethylene, methylene chloride, acetone, cyclopentane, 2-methylpentane, hydrofluoroolefins having a boiling point in a range of from about 30° C. to about 75° C., HFO-1336mzz-Z, hydrofluoroethers having a boiling point in a range of from about 30° C. to about 75° C., HFE-347pcF, and combinations thereof.

6. The composition of claim 1, wherein the phase-change fluid comprises a fluorinated phase-change fluid selected from the group consisting of hydrofluoroolefins having a boiling point in a range of from about 30° C. to about 75° C., HFO-1336mzz-Z, hydrofluoroethers having a boiling point in a range of from about 30° C. to about 75° C., HFE-347pcF, and combinations thereof.

7. The composition of claim 1, wherein the phase-change fluid comprises a non-fluorinated phase-change fluid selected from the group consisting of trans-dichloroethylene, methylene chloride, acetone, cyclopentane, 2-methylpentane, and combinations thereof.

8. The composition of claim 1, wherein the dielectric fluid is a fluorinated dielectric fluid and wherein the phase-change fluid is a non-fluorinated phase-change fluid.

9. The composition of claim 1, wherein the dielectric fluid comprises a component selected from the group consisting of perfluoropolyether oils, perfluorocarbons, perfluorohexane, perfluoroalkenes, perfluoroheptene, perfluoroketones, dodecafluoro-2-methylpentan-3-one, and combinations thereof, and wherein the phase-change fluid comprises a component selected from the group consisting of trans-dichloroethylene, methylene chloride, acetone, cyclopentane, 2-methylpentane, and combinations thereof.

10. The composition of claim 1, wherein the dielectric fluid comprises perfluorohexane and wherein the phase-change fluid comprises methylene chloride.

11. The composition of claim 1, wherein the dielectric fluid comprises a perfluoropolyether oil and wherein the phase-change fluid comprises trans-dichloroethylene.

12. The composition of claim 1, wherein the dielectric fluid is a hydrocarbon dielectric fluid and wherein the phase-change fluid is a fluorinated phase-change fluid.

13. The composition of claim 1, wherein the dielectric fluid comprises a component selected from the group consisting of mineral oils, alkanes having at least eight carbon atoms, silicone oils, polyol ester oils, polyalkylene glycol oils, and combinations thereof, and wherein the phase-change fluid comprises a component selected from the group consisting of hydrofluoroolefins having a boiling point in a range of from about 30° C. to about 75° C., HFO-1336mzzZ, hydrofluoroethers having a boiling point in a range of from about 30° C. to about 75° C. HFE-347pcF, and combinations thereof.

14. The composition of claim 1, wherein the dielectric fluid comprises a mineral oil and wherein the phase-change fluid comprises HFO-1336mzzZ.

15. The composition of claim 1, wherein the dielectric fluid has a dielectric constant greater than 1.0 and less than 8.0.

16. An immersion cooling unit comprising:
an immersion cell, defining an internal cavity;
i) an electronic component in the internal cavity;
ii) a working fluid partially filling the internal cavity; and
iii) a heat transfer device;
wherein the working fluid includes a composition comprising a dielectric fluid and a phase-change fluid, wherein the dielectric fluid and the phase-change fluid are immiscible, and wherein the dielectric fluid has a boiling point greater than a boiling point of the phase-change fluid; and
wherein the dielectric fluid at least partially immerses the electronic component.

17-36. (canceled)

37. A method for cooling an electrical component comprising:
at least partially immersing an electrical component in a working fluid; and
transferring heat from the electrical component using the working fluid;
wherein the working fluid includes a composition comprising a dielectric fluid and a phase-change fluid, wherein the dielectric fluid and the phase-change fluid are immiscible, and wherein the dielectric fluid has a boiling point greater than a boiling point of the phase-change fluid; and
wherein the electronic component is at least partially immersed in the dielectric fluid of the working fluid.

38-71. (canceled)
